(19) United States
(12) Patent Application Publication
(10) Pub. No.: US 2008/0197496 A1
(43) Pub. Date: Aug. 21, 2008

(54) Semiconductor device having at least two layers of wirings stacked therein and method of manufacturing the same

(75) Inventors: Kenichi Mori, Tokyo (JP); Kazuyoshi Maekawa, Tokyo (JP); Noriaki Amo, Itami-shi (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/071,200

(22) Filed: Feb. 19, 2008

(30) Foreign Application Priority Data
Feb. 19, 2007 (JP) 2007-038288 (P)

(51) Int. Cl. H01L 23/52; H01L 21/4763

(52) U.S. Cl. 257/751; 438/627; 257/E23.141; 257/E21.495

(57) ABSTRACT

A semiconductor device according to the present invention is a semiconductor device having a first wiring formed in a first insulating layer and a second wiring formed in a second insulating layer formed on the first insulating layer and the first wiring. Here, at least one of the first wiring and the second wiring is a CuAl wiring. The second wiring is electrically connected to the first wiring at its via-plug portion, with a plurality of barrier layers interposed between the second wiring and the first wiring. In the barrier layers, a CuAl-contact barrier layer which is in contact with the CuAl wiring has a nitrogen atom content of less than 10 atomic %. Therefore, the present semiconductor device has high reliability and small variations in initial via resistance value.

### BACKGROUND OF THE INVENTION

1. Field of the Invention

The present invention relates to a semiconductor device having at least two layers of wirings stacked therein and a method of manufacturing the same. Specifically, the present invention relates to a semiconductor device having a first wiring formed in a first insulating layer and a second wiring formed in a second insulating layer formed on the first insulating layer and the first wiring, and a method of manufacturing the same.

2. Description of the Background Art

After the development of wirings in the 130 nm node generation, copper has widely been used as a wiring material in semiconductor devices instead of an aluminum-based alloy (which refers to an alloy having a composition of aluminum of at least 50 atomic %, the same applies to the following), for the purpose of reducing resistance of the wiring. Consequently, as a method of forming a wiring, a so-called dual damascene method has been used instead of a method of directly processing a wiring material by dry etching. The dual damascene method includes forming in advance a trench and a via-hole at sites of an interlayer insulating film where a wiring and a via are to be formed, embedding copper serving as a wiring material in the trench and the via-hole, and removing an excess part of the copper by a CMP method (which refers to a chemical mechanical polishing method, the same applies to the following).

With the above-described changes in wiring material and method of forming a wiring, a new type of problem referred to as an SIV (Stress Induced Voiding, the same applies to the following) arises in addition to the conventional EM (Electro Migration, the same applies to the following), for example, and hence ensuring reliability in a Cu wiring has become a challenge much more important and difficult than ever before. As to improvement in reliability of the Cu wiring, various proposals have been made. Among them, there is a proposal that a Cu wiring be alloyed (e.g. see Japanese Patent Laying-Open No. 2004-031847 (Patent Document 1), Y. Matsubara et al., “Thermally robust 90 nm node Cu—Al wiring technology using solid phase reaction between Cu and Al”, VLSI Tech Dig., 2003, pp. 127-128 (Non-Patent Document 1), T. Tonegawa et al., “Suppression of Bimodal Stress-Induced Voiding using High-diffusive Dopant from Cu-alloy Seed Layer”, Proc. of IITC, 2003, pp. 216-218 (Non-Patent Document 2), and K. Maekawa et al., “Improvement in Reliability of Cu Dual-Damascene Interconnects Using Cu—Al Alloy Seed”, Proc. of AMC, 2004, pp. 221-226 (Non-Patent Document 3)). As discussed in these documents, various elements such as Sn, Ti, and Al have been proposed as an element to be added in alloying of Cu. Furthermore, there have been proposed various methods of adding additive elements and various mechanisms of improving reliability.

We also focus on a CuAl alloy, and improve reliability by alloying a seed layer prior to formation of Cu plating and thereby forming a CuAl wiring. As to EM tolerance and SIV tolerance of the via portion, improvement that meets our expectations has been achieved.

### SUMMARY OF THE INVENTION

A measurement of initial via resistance of a semiconductor device that uses the above-described CuAl wiring showed that via resistance values varied greatly.

Therefore, detailed studies were made on the relationship between a material that forms a wiring, and a material that forms a barrier layer provided between the wiring and an insulating layer for preventing diffusion of metal atoms from the wiring to the insulating layer. At present, a Ta barrier layer is used, and in addition, Ta/TaN stacked barrier layers in which a Ta barrier layer serving as an upper layer and a TaN barrier layer serving as a lower layer are stacked are used for further enhancing the effect of preventing diffusion of metal atoms, as the barrier layer.

As to a semiconductor device shown in FIG. 23 (hereinafter referred to as a device A), which uses Cu wirings 12m, 22m, barrier layers 14 having a Ta barrier layer 14s and a TaN barrier layer 14t stacked therein, and barrier layers 24 having a Ta barrier layer 24s and a TaN barrier layer 24t stacked therein, a semiconductor device shown in FIG. 24 (hereinafter referred to as a device B), which uses CuAl wirings 12n, 22n, barrier layers 14 having Ta barrier layer 14s and TaN barrier layer 14t stacked therein, and barrier layers 24 having Ta barrier layer 24s and TaN barrier layer 24t stacked therein, and a semiconductor device shown in FIG. 25 (hereinafter referred to as a device C), which uses CuAl wirings 12n, 22n, and Ta barrier layers 14s, 24s, via resistance of each of the devices was measured. As shown in FIG. 26, device A exhibits the smallest variations in via resistance value. Device C exhibits greater variations than device A does, device B exhibits greater variations than device C does, and device B exhibits the greatest variations. In other words, if barrier layers having a Ta barrier layer and a TaN barrier layer stacked therein were used, variations in via resistance became greater in the case where a CuAl wiring was used as a wiring, than in the case where a Cu wiring was used. If a CuAl wiring was used, it was found that variations in via resistance value could be made smaller in the case where a Ta barrier layer was used as a barrier layer, than in the case where barrier layers having a Ta barrier layer and a TaN barrier layer stacked therein were used.

Here, a first CuAl wiring 12n is in contact with TaN barrier layer 24t serving as a lower layer of barrier layers 24 in device B in FIG. 24, while first CuAl wiring 12n is in contact with Ta barrier layer 24s in device C in FIG. 25.

According to the experimental results described above, the reason why variations in via resistance became large in device B in FIG. 24 is considered to be that the CuAl wiring and the TaN barrier layer were brought into contact with each other and a substance such as AlN which has resistance higher than that of a metal (which includes a simple metal substance and an alloy, the same applies to the following) was formed. Note that a curve A, a curve B, and a curve C in FIG. 26 show measurement results as to device A, device B, and device C, respectively.

Therefore, an object of the present invention is to provide a semiconductor device that overcomes the above-described problems, and has high reliability and small variations in initial via resistance value, and a method of manufacturing the same.

An embodiment of the semiconductor device according to the present invention is a semiconductor device having a first wiring formed in a first insulating layer and a second wiring formed in a second insulating layer formed on the first insulating layer and the first wiring. Here, at least one of the first wiring and the second wiring is a CuAl wiring. The second wiring is electrically connected to the first wiring at its via-plug portion, with a plurality of barrier layers interposed between the second wiring and the first wiring. In the barrier layers, a CuAl-contact barrier layer which is in contact with the CuAl wiring has a nitrogen atom content of less than 10 atomic %.

Furthermore, an embodiment of the method of manufacturing a semiconductor device according to the present invention includes the steps of: preparing a first wiring formed in a first insulating layer; forming a second insulating layer on the first insulating layer and the first wiring; forming a trench for wiring and a via-hole which reaches the first wiring in the second insulating layer; forming a plurality of barrier layers in the trench for wiring and the via-hole; and forming a second wiring on the barrier layers. Here, at least one of the first wiring and the second wiring is formed of a CuAl alloy. In the barrier layers, a CuAl-contact barrier layer which is in contact with a CuAl wiring formed of the CuAl alloy has a nitrogen atom content of less than 10 atomic %.

According to the above-described embodiments of the present invention, it is possible to provide a semiconductor device which has high reliability and small variations in initial via resistance value, and a method of manufacturing the same.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing an embodiment of a semiconductor device according to the present invention.

FIG. 2 is a schematic cross-sectional view showing a step of preparing a first wiring in a method of manufacturing the semiconductor device in FIG. 1.

FIG. 3 is a schematic cross-sectional view showing a step of forming a trench for wiring and a via-hole after the step in FIG. 2.

FIG. 4 is a schematic cross-sectional view showing a step of forming barrier layers after the step in FIG. 3.

FIG. 5 is a schematic cross-sectional view showing a step of embedding a wiring material after the step in FIG. 4.

FIG. 6 is a schematic cross-sectional view showing a step of processing the wiring material after the step in FIG. 5.

FIG. 7 is a schematic cross-sectional view showing another embodiment of the semiconductor device according to the present invention.

FIG. 8 is a schematic cross-sectional view showing a step of preparing a first wiring in a method of manufacturing the semiconductor device in FIG. 7.

FIG. 9 is a cross-sectional view showing a step of forming a trench for wiring and a via-hole after the step in FIG. 8.

FIG. 10 is a cross-sectional view showing a step of selectively forming a first barrier layer after the step in FIG. 9.

FIG. 11 is a cross-sectional view showing a step of forming barrier layers after the step in FIG. 10.

FIG. 12 is a schematic cross-sectional view showing a step of embedding a wiring material after the step in FIG. 11.

FIG. 13 is a schematic cross-sectional view showing a step of processing the wiring material after the step in FIG. 12.

FIG. 14 is a schematic cross-sectional view showing still another embodiment of the semiconductor device according to the present invention.

FIG. 15 is a schematic cross-sectional view showing a step of preparing a first wiring in a method of manufacturing the semiconductor device in FIG. 14.

FIG. 16 is a schematic cross-sectional view showing a step of selectively forming a first barrier layer after the step in FIG. 15.

FIG. 17 is a schematic cross-sectional view showing a step of forming a trench for wiring and a via-hole after the step in FIG. 16.

FIG. 18 is a schematic cross-sectional view showing a step of forming barrier layers after the step in FIG. 17.

FIG. 19 is a schematic cross-sectional view showing a step of embedding a wiring material after the step in FIG. 18.

FIG. 20 is a schematic cross-sectional view showing a step of processing the wiring material after the step in FIG. 19.

FIGS. 21 and 22 are schematic cross-sectional views each showing a further embodiment of the semiconductor device according to the present invention.

FIG. 23 is a schematic cross-sectional view showing an example of a semiconductor device.

FIG. 24 is a schematic cross-sectional view showing another example of a semiconductor device.

FIG. 25 is a schematic cross-sectional view showing still another example of a semiconductor device.

FIG. 26 is a graph showing cumulative frequency distribution of via resistance of the semiconductor devices.

### DESCRIPTION OF THE PREFERRED EMBODIMENTS

### First Embodiment

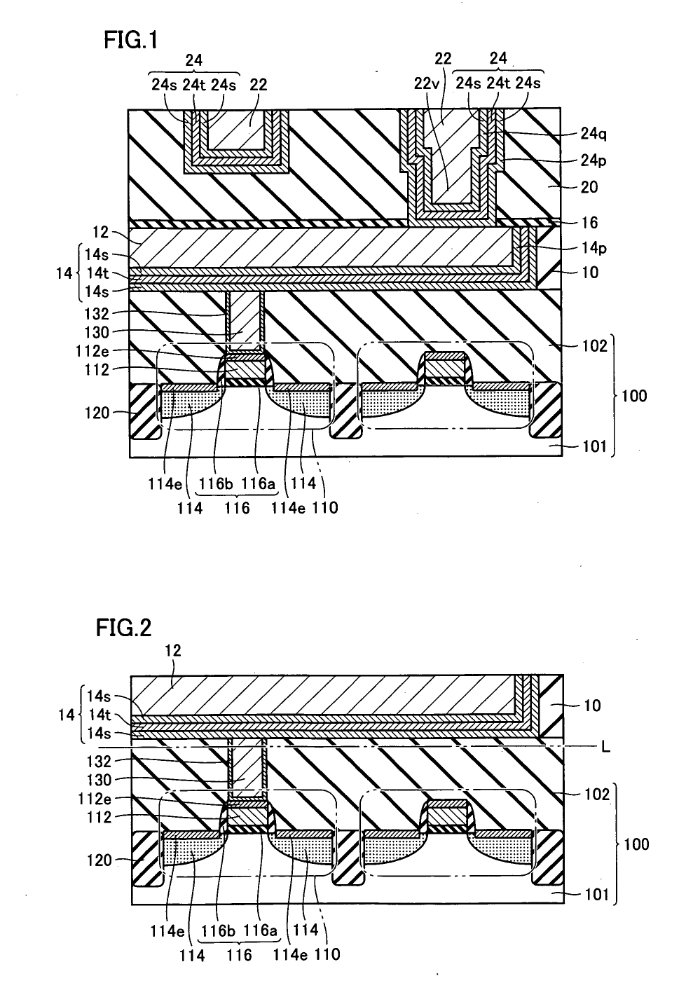

With reference to FIG. 1, an embodiment of a semiconductor device according to the present invention is a semiconductor device having a first wiring 12 formed in a first insulating layer 10 and a second wiring 22 formed in a second insulating layer 20 formed on first insulating layer 10 and first wiring 12. Here, at least one of first wiring 12 and second wiring 22 is a CuAl wiring formed of a CuAl alloy. Second wiring 22 is electrically connected to first wiring 12 at its via-plug portion 22v, with a plurality of barrier layers 24 interposed therebetween. In the plurality of barrier layers 24, a CuAl-contact barrier layer which is in contact with the CuAl wiring has a nitrogen atom content of less than 10 atomic %, and preferably less than 1 atomic %. Here, it is preferable that a barrier layer 24s mainly contains metal atoms from a viewpoint of reducing electrical resistance between the wirings, and specifically has a metal atom content of at least 90 atomic %.

In the present embodiment, the CuAl-contact barrier layer which is in contact with the CuAl wiring has a small nitrogen atom content of less than 10 atomic %, so that a high-resistance substance such as AlN is prevented from being formed between the wiring and the barrier layer, and variations in initial via resistance become small. From such a viewpoint, the CuAl-contact barrier layer preferably has a nitrogen atom content of less than 1 atomic %. In the present embodiment, a Ta barrier layer having a nitrogen atom content of less than 1 atomic % is used as the CuAl-contact barrier layer.

Here, the nitrogen atom content of the barrier layer can be measured with a fluorescent X-ray analysis method and others. In the present embodiment, it is preferable that both of the first wiring and the second wiring are CuAl wirings from a viewpoint of enhancing reliability.

Furthermore, it is preferable that at least one of the plurality of barrier layers described above has a nitrogen atom content of at least 10 atomic %. A barrier layer which has a nitrogen atom content of at least 10 atomic % has high barrier properties, and can enhance reliability of the semiconductor device. Accordingly, assuming that the same barrier properties are ensured, a plurality of barrier layers which include at least one barrier layer having a nitrogen atom content of at least 10 atomic % can achieve a total thickness much smaller than a total thickness of a plurality of barrier layers which do not include a barrier layer having a nitrogen atom content of at least 10 atomic %, so that resistance between the wirings can further be reduced.

With reference to FIG. 1, a semiconductor device according to the present embodiment will hereinafter be described specifically. The semiconductor device according to the present embodiment has a base 100 including a semiconductor element 110. Semiconductor element 110 is configured with, for example, a MOS FET (metal oxide semiconductor field effect transistor, the same applies to the following). The MOS FET has paired source/drain regions 114, a gate insulating layer 116, and a gate electrode layer 112. Paired source/drain regions 114 are formed such that they are spaced apart from each other at a surface of semiconductor substrate 101 and in proximity thereof. Gate electrode layer 112 is formed on a region of the semiconductor substrate placed between paired source/drain regions 114, with gate insulating layer 116 interposed therebetween. Note that gate insulating layer 116 is configured with a bottom surface insulating layer 116a and a side surface insulating layer 116b. At surfaces of paired source/drain regions 114 and a surface of gate electrode layer 112, there are formed nickel silicide layers 114e, 112e, respectively. At the surface of semiconductor substrate 101 and in the proximity thereof, there is formed an element separation insulating layer 120 for insulating each semiconductor element 110. Furthermore, an interlayer insulating layer 102 is formed on semiconductor substrate 101 and semiconductor element 110. In interlayer insulating layer 102, there is formed a tungsten plug. 130 (hereinafter referred to as W plug 130) for electrically connecting gate electrode layer 112 and first wiring 12, which will be described below. At a surface of W plug 130, a Ti/TiN barrier layer 132 is formed.

First insulating layer 10 is formed on the above-described base 100, and first wiring 12 is formed in first insulating layer 10. First wiring 12 is a CuAl wiring formed of a CuAl alloy. Note that there are formed the plurality of barrier layers 14, namely, a Ta barrier layer 14s, a TaN barrier layer 14t, and Ta barrier layer 14s in this order when seen from first insulating layer 10, between first insulating layer 10 and first wiring 12.

On first insulating layer 10 and first wiring 12, second insulating layer 20 is formed with a liner layer 16 interposed therebetween. Second wiring 22 is formed in second insulating layer 20. Second wiring 22 is a CuAl wiring formed of a CuAl alloy as in the case of first wiring 12. Second wiring 22 is electrically connected to first wiring 12 at its via-plug portion 22v with the plurality of barrier layers 24 interposed therebetween. In other words, liner layer 16 in a region directly below via-plug portion 22v of second wiring 22 is removed to ensure electrical connection between first wiring 12 and second wiring 22. In order to ensure electrical connection between first wiring 12 and second wiring 22, the plurality of barrier layers 24 are made of a conductive material such as a metal.

As the plurality of barrier layers 24, a Ta barrier layer 24s, a TaN barrier layer 24t, and Ta barrier layer 24s are formed in this order when seen from first wiring 12 and second insulating layer 20, between first wiring 12 and second wiring 22 and between second insulating layer 20 and second wiring 22. Here, each of a first barrier layer 24p (Ta barrier layer 24s) identified as a CuAl-contact barrier layer which is in contact with first wiring 12 identified as a CuAl wiring, and a second barrier layer 24q (Ta barrier layer 24s) identified as a CuAl-contact barrier layer which is in contact with second wiring 22 identified as a CuAl wiring, has a small nitrogen atom content of less than 1 atomic %. Therefore, a high-resistance substance such as AlN is prevented from being formed between first wiring 12 and first barrier layer 24p, and between second wiring 22 and second barrier layer 24q, and hence variations in via resistance become small.

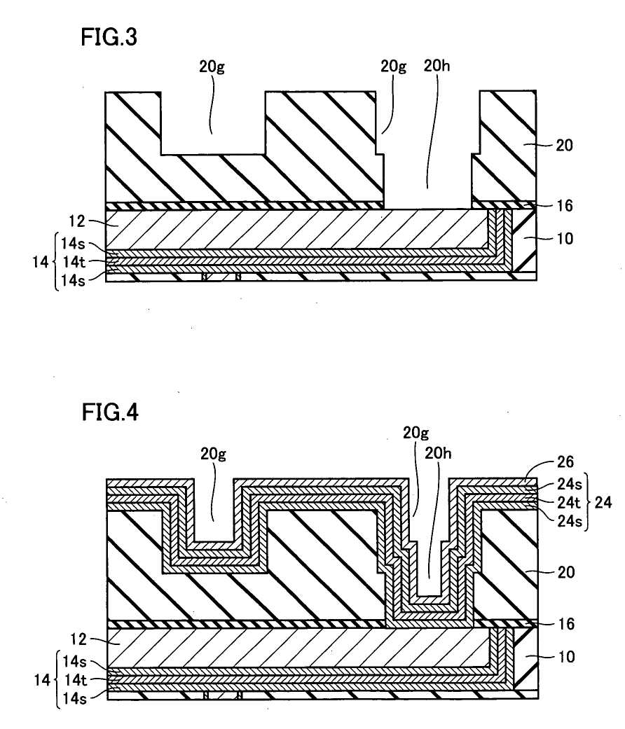

With reference to FIGS. 1-6, a method of manufacturing the semiconductor device according to the present embodiment will hereinafter be described specifically. Note that an illustration of a portion of base 100 lower than a two-dot chain line L in FIG. 2 is eliminated for simplicity in FIGS. 3-6.

Initially, with reference to FIG. 2, there is prepared first wiring 12 formed in first insulating layer 10 formed on base 100 including semiconductor element 110 (a step of preparing the first wiring). Here, first wiring 12 is a CuAl wiring, and the plurality of barrier layers 14 are Ta barrier layer 14s, TaN barrier layer 14t, and Ta barrier layer 14s arranged in this order when seen from first insulating layer 10.

Next, with reference to FIG. 3, on first insulating layer 10 and first wiring 12 in the wafer prepared in the above-described step of preparing the first wiring, an SiCN, layer is formed as liner layer 16 by a CVD (chemical vapor deposition) method, then an SiO₂ layer is formed as second insulating layer 20 by a CVD method, and a trench 20g for wiring and a via-hole 20h which reaches first wiring 12 are formed in second insulating layer 20 by dry etching (a step of forming the trench for wiring and the via-hole).

Next, with reference to FIG. 4, on second insulating layer 20 in which trench 20g for wiring and via-hole 20h are formed, Ta barrier layer 24s, TaN barrier layer 24t, and Ta barrier layer 24s are formed in this order as the plurality of barrier layers 24 by a PVD (physical vapor deposition) method, and a seed layer 26 is formed of a CuAl alloy (a step of forming the barrier layers).

Next, with reference to FIG. 5, a Cu layer 27 is formed by a plating method such that Cu layer 27 is embedded in trench 20g for wiring and via-hole 20h in second insulating layer 20 (a step of embedding a wiring material).

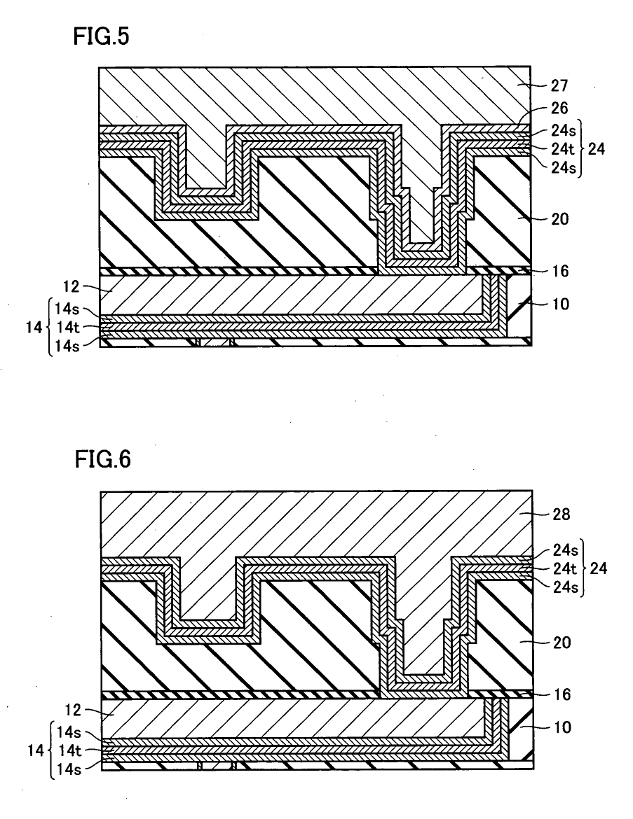

Next, with reference to FIG. 6, Al atoms in seed layer 26 made of a CuAl alloy are diffused into Cu layer 27 by heat treatment to form a CuAl layer 28 (a step of processing the wiring material).

Next, with reference to FIG. 1, portions of barrier layers 24 and CuAl layer 28 on a surface of second insulating layer 20 are removed by a CMP method to form second wiring 22 in trench 20g for wiring and via-hole 20h (a step of forming the second wiring).

In the semiconductor device manufactured as such, barrier layers 24 are made as three layers, and each of first barrier layer 24p and second barrier layer 24q identified as CuAl-contact barrier layers which are in contact with first wiring 12 and second wiring 22 identified as CuAl wirings, respectively, is Ta barrier layer 24s which has a nitrogen atom content of less than 1 atomic %. Accordingly, a high-resistance substance such as AlN is prevented from being formed between the wiring and the barrier layer, and hence variations in via resistance become small.

In the present embodiment, the barrier layers include three layers. However, the number of barrier layers is not limited thereto as long as first barrier layer 24p and second barrier layer 24q which are in contact with first wiring 12 and second wiring 22 identified as CuAl wirings, respectively, are barrier layers each of which has a nitrogen atom content of less than 10 atomic %. Furthermore, from the above-described viewpoint, each of first barrier layer 24p and second barrier layer 24q preferably has a nitrogen atom content of less than 1 atomic %.

The present embodiment has been described mainly taking as an example the case where both of the first wiring and the second wiring are CuAl wirings. However, the present embodiment may also be applied to the case where one of the second wiring and the first wiring is a Cu wiring, as long as at least one of the first wiring and the second wiring is a CuAl wiring. If one of the second wiring and the first wiring is a Cu wiring, a barrier layer which is in contact with the Cu wiring may contain nitrogen atoms. Furthermore, if a Cu wiring is formed in the insulating layer, the step of processing the wiring material is unnecessary in the manufacturing steps described above.

In the present embodiment, a Ta layer, a Ta alloy layer, and a Ta compound layer are used as the barrier layers. However, the barrier layers are not particularly limited thereto as long as they have barrier properties against Cu atoms. It is possible to use a Ti layer, a Ti alloy layer, and a Ti compound layer, a W layer, a W alloy layer, and a W compound layer, an Ru layer, an Ru alloy layer, and an Ru compound layer, and others. Furthermore, although the present embodiment has been described taking a dual damascene structure as an example, the present embodiment can also be applied to a single damascene structure.

### Second Embodiment

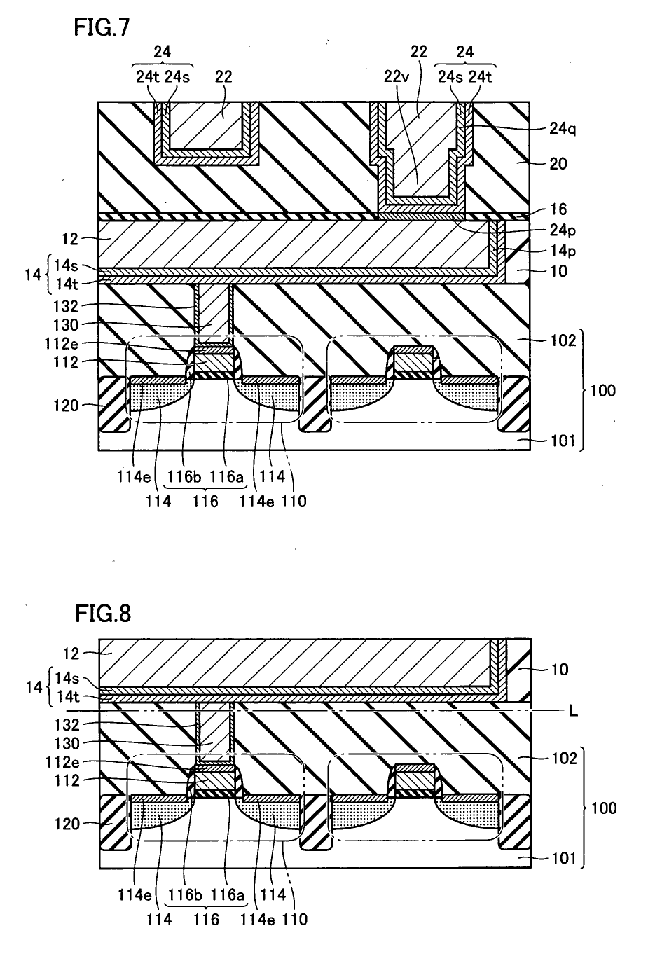

With reference to FIG. 7, another embodiment of the semiconductor device according to the present invention is a semiconductor device which has first wiring 12 formed in first insulating layer 10, and second wiring 22 formed in second insulating layer 20 formed on first insulating layer 10 and first wiring 12. Here, at least one of first wiring 12 and second wiring 22 is a CuAl wiring formed of a CuAl alloy. Second wiring 22 is electrically connected to first wiring 12 at its via-plug portion 22v with the plurality of barrier layers 24 interposed therebetween. In the plurality of barrier layers 24, a CuAl-contact barrier layer which is in contact with the CuAl wiring has a nitrogen atom content of less than 10 atomic %, and preferably less than 1 atomic %. Here, the semiconductor device according to the present embodiment is characterized in that first barrier layer 24p which is in contact with first wiring 12 is selectively formed directly below via-plug portion 22v of second wiring 22.

In the present embodiment, the CuAl-contact barrier layer which is in contact with the CuAl wiring has a small nitrogen atom content of less than 10 atomic %, and hence a high-resistance substance such as AlN is prevented from being formed between the wiring and the barrier layer, and variations in initial via resistance become small. Furthermore, from a viewpoint of enhancing reliability, both of the first wiring and the second wiring are preferably CuAl wirings in the present embodiment.

With reference to FIG. 7, the semiconductor device according to the present embodiment will hereinafter be described specifically. The semiconductor device according to the present embodiment has base 100 including semiconductor element 110. Such base 100 is similar to the base in the first embodiment.

First insulating layer 10 is formed on the above-described base 100, and first wiring 12 is formed in first insulating layer 10. First wiring 12 is a CuAl wiring formed of a CuAl alloy. Note that the plurality of barrier layers 14, namely, TaN barrier layer 14t and Ta barrier layer 14s are formed in this order when seen from first insulating layer 10 between first insulating layer 10 and first wiring 12.

On first insulating layer 10 and first wiring 12, there is formed second insulating layer 20 with liner layer 16 interposed therebetween. Second wiring 22 is formed in second insulating layer 20. Second wiring 22 is a CuAl wiring formed of a CuAl alloy as in the case of first wiring 12. Second wiring 22 is electrically connected to first wiring 12 at its via-plug portion 22v with the plurality of barrier layers 24 interposed therebetween. In other words, liner layer 16 in a region directly below via-plug portion 22v of second wiring 22 is removed to selectively form a tungsten layer (hereinafter referred to as a W layer) serving as first barrier layer 24p, so that electrical connection between first wiring 12 and second wiring 22 is ensured. In order to ensure electrical connection between first wiring 12 and second wiring 22, the plurality of barrier layers 24 are formed of a conductive material such as a metal.

As the plurality of barrier layers 24, the W layer (first barrier layer 24p), TaN barrier layer 24t, and Ta barrier layer 24s are formed in this order when seen from first wiring 12 between first wiring 12 and second wiring 22, and TaN barrier layer 24t and Ta barrier layer 24s are formed in this order when seen from second insulating layer 20 between second insulating layer 20 and second wiring 22. Here, each of first barrier layer 24p (W layer) identified as a CuAl-contact barrier layer which is in contact with first wiring 12 identified as a CuAl wiring, and second barrier layer 24q (Ta barrier layer 24s) identified as a CuAl-contact barrier layer which is in contact with second wiring 22 identified as a CuAl wiring, has a small nitrogen atom content of less than 1 atomic %. Accordingly, a high-resistance substance such as AlN is prevented from being formed between first wiring 12 and first barrier layer 24p, and between second wiring 22 and second barrier layer 24q, and hence variations in via resistance become small.

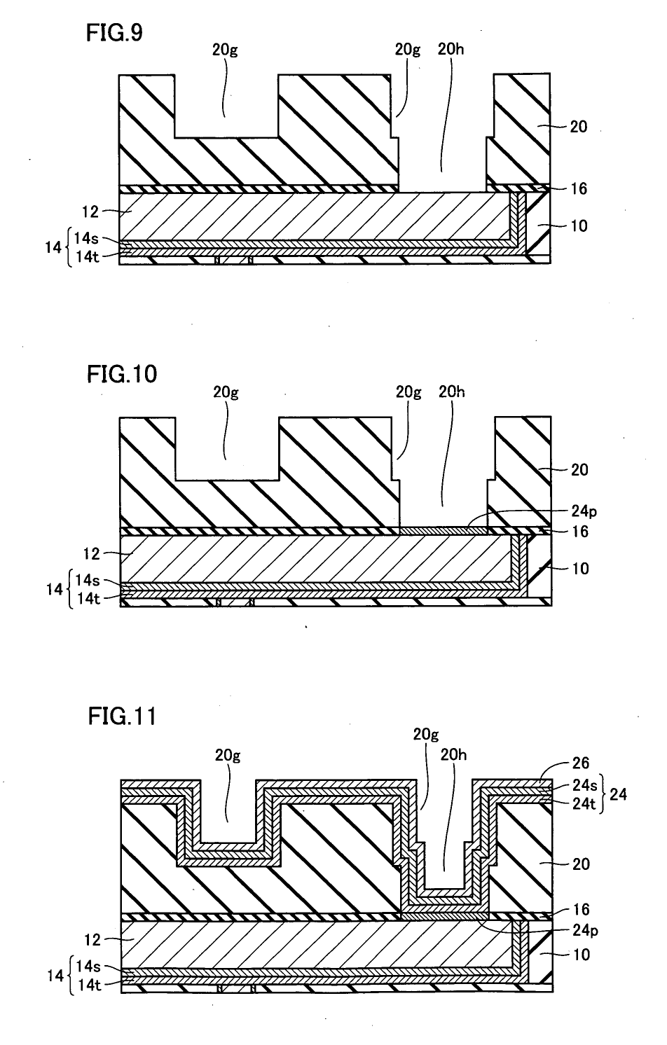

With reference to FIGS. 7-13, a method of manufacturing the semiconductor device according to the present embodiment will hereinafter be described specifically. Note that an illustration of a portion of base 100 lower than a two-dot chain line L in FIG. 8 is eliminated for simplicity in FIGS. 9-13.

Initially, with reference to FIG. 8, there is prepared first wiring 12 formed in first insulating layer 10 formed on base 100 including semiconductor element 110 (a step of preparing the first wiring). Here, first wiring 12 is a CuAl wiring, and the plurality of barrier layers 14 are TaN barrier layer 14t and Ta barrier layer 14s arranged in this order when seen from the first insulating layer.

Next, with reference to FIG. 9, on first insulating layer 10 and first wiring 12 in the wafer prepared in the above-described step of preparing the first wiring, an SiCN layer is formed as liner layer 16 by a CVD method, then an SiO₂ layer is formed as second insulating layer 20 by a CVD method, and trench 20g for wiring and via-hole 20h which reaches first wiring 12 are formed in second insulating layer 20 by dry etching (a step of forming the trench for wiring and the via-hole).

Next, with reference to FIG. 10, the W layer is selectively formed as first barrier layer 24p by a selective CVD method directly on the first wiring exposed at a bottom portion of via-hole 20h (a step of selectively forming the first barrier layer).

Next, with reference to FIG. 11, TaN barrier layer 24t and Ta barrier layer 24s are formed in this order as the plurality of barrier layers 24 by a PVD method, on second insulating layer 20 in which trench 20g for wiring and via-hole 20h are formed, and on first barrier layer 24p formed selectively. Seed layer 26 is formed of a CuAl alloy (a step of forming the barrier layers).

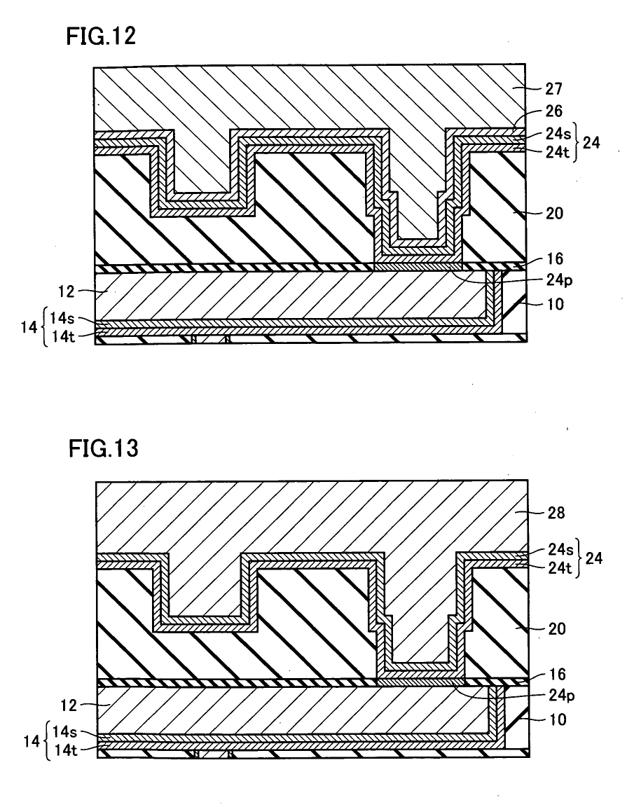

Next, with reference to FIG. 12, Cu layer 27 is formed by a plating method such that Cu layer 27 is embedded in trench 20g for wiring and via-hole 20h in second insulating layer 20 (a step of embedding a wiring material).

Next, with reference to FIG. 13, Al atoms in seed layer 26 formed of a CuAl alloy are diffused into Cu layer 27 by a heat treatment to form CuAl layer 28 (a step of processing the wiring material).

Next, with reference to FIG. 7, portions of barrier layers 24 and CuAl layer 28 on the surface of second insulating layer 20 are removed by a CMP method to form second wiring 22 in trench 20g for wiring and via-hole 20h (a step of forming the second wiring).

In the semiconductor device manufactured as such, first barrier layer 24p (W layer) and second barrier layer 24q (Ta barrier layer 24s) which are in contact with first wiring 12 and second wiring 22 identified as CuAl wiring, respectively, have a small nitrogen atom content of less than 10 atomic %, so that a high-resistance substance such as AlN is prevented from being formed between the wiring and the barrier layer, and hence variations in via resistance become small.

Furthermore, in the semiconductor device according to the present embodiment, first barrier layer 24p which has a nitrogen atom content of less than 1 atomic % is only required to be formed directly below via-plug portion 22v of second wiring 22, and is not required to be formed at a portion other than an electrically-connected portion of the wiring. Therefore, it is possible to simplify the structure of barrier layers at the portion other than the electrically-connected portion of the wiring.

In the present embodiment, selective forming of first barrier layer 24p directly below via-plug portion 22v of second wiring 22 is performed by selectively forming a W layer by a selective CVD method. However, selective forming is not particularly limited thereto as long as a barrier layer having a nitrogen atom content of less than 10 atomic % is selectively formed. Selective forming may be performed by selectively forming a metal layer mainly composed of cobalt (e.g. a CoW layer, a CoWP layer, a CoWB layer, a CoWPB layer and others) by an electroless plating method.

In the present embodiment, three barrier layers are used at the electrically-connected portion of the wiring, and two barrier layers are used at a portion other than the electrically-connected portion. However, the number of barrier layers is not limited thereto as long as barrier layers having a nitrogen atom content of less than 10 atomic % are used as first barrier layer 24p and second barrier layer 24q which are in contact with first wiring 12 and second wiring 22 identified as CuAl wirings, respectively. Furthermore, from the above-described viewpoint, first barrier layer 24p and second barrier layer 24q preferably have a nitrogen atom content of less than 1 atomic %. Furthermore, as in the first embodiment, at least one of the plurality of barrier layers described above has a nitrogen atom content of at least 10 atomic %.

The present embodiment has been described mainly taking as an example the case where both of the first wiring and the second wiring are CuAl wirings. However, the present embodiment may also be applied to the case where one of the second wiring and the first wiring is a Cu wiring, as long as at least one of the first wiring and the second wiring is a CuAl wiring. If one of the second wiring and the first wiring is a Cu wiring, a barrier layer which is in contact with the Cu wiring may contain nitrogen atoms. Furthermore, if Cu is formed in the insulating layer, the step of processing the wiring material is unnecessary in the manufacturing steps described above.

In the present embodiment, a Ta layer, a Ta alloy layer, and a Ta compound layer are used as the barrier layers. However, the barrier layers are not particularly limited thereto as long as they have barrier properties against Cu atoms. It is possible to use a Ti layer, a Ti alloy layer, and a Ti compound layer, a W layer, a W alloy layer, and a W compound layer, an Ru layer, an Ru alloy layer, and an Ru compound layer, and others. Furthermore, although the present embodiment has been described taking a dual damascene structure as an example, the present embodiment can also be applied to a single damascene structure.

### Third Embodiment

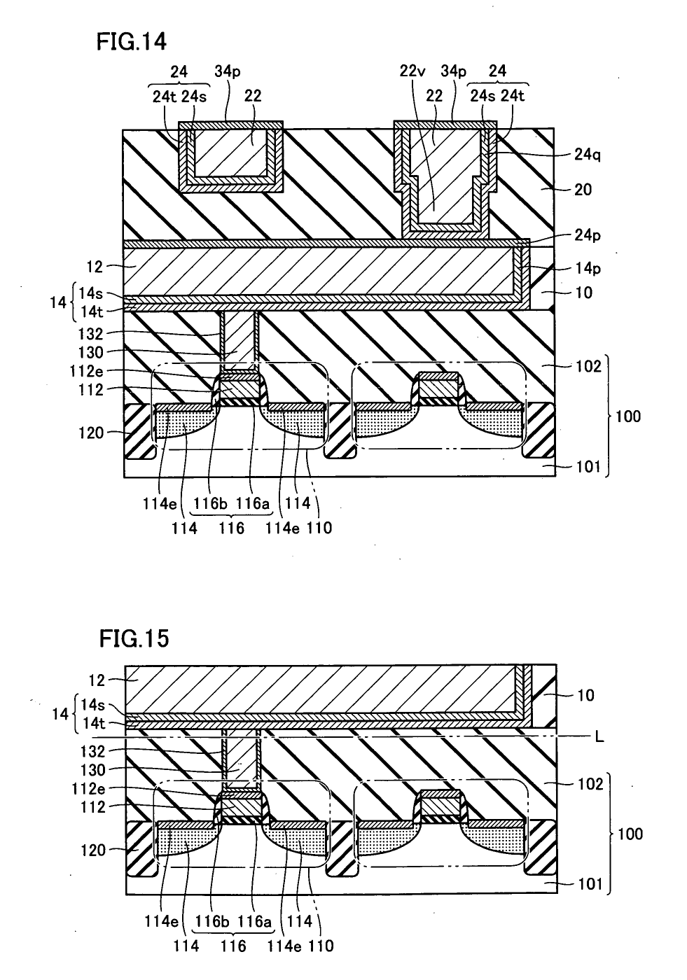

With reference to FIG. 14, still another embodiment of the semiconductor device according to the present invention is a semiconductor device having first wiring 12 formed in first insulating layer 10, and second wiring 22 formed in second insulating layer 20 formed on first insulating layer 10 and first wiring 12. Here, at least one of first wiring 12 and second wiring 22 is a CuAl wiring formed of a CuAl alloy. Second wiring 22 is electrically connected to first wiring 12 at is via-plug portion 22v with the plurality of barrier layers 24 formed of a metal interposed therebetween. In the plurality of barrier layers 24, a CuAl-contact barrier layer which is in contact with the CuAl wiring has a nitrogen atom content of less than 10 atomic %, and preferably less than 1 atomic %. Here, the semiconductor device according to the present embodiment is characterized in that first barrier layer 24p which is in contact with first wiring 12 is selectively formed directly on first wiring 12.

In the present embodiment, the CuAl-contact barrier layer which is in contact with the CuAl wiring has a small nitrogen atom content of less than 10 atomic %, and hence a high-resistance substance such as AlN is prevented from being formed between the wiring and the barrier layer, and variations in initial via resistance become small. Furthermore, from a viewpoint of enhancing reliability, both of the first wiring and the second wiring are CuAl wirings in the present embodiment.

With reference to FIG. 14, the semiconductor device according to the present embodiment will hereinafter be described specifically. The semiconductor device according to the present embodiment has base 100 including semiconductor element 110. Such base 100 is similar to the base in the first embodiment.

First insulating layer 10 is formed on the above-described base 100, and first wiring 12 is formed in first insulating layer 10. First wiring 12 is a CuAl wiring formed of a CuAl alloy. Note that the plurality of barrier layers 14, namely, TaN barrier layer 14t and Ta barrier layer 14s are formed in this order when seen from first insulating layer 10 between first insulating layer 10 and first wiring 12. Directly on first wiring 12, there is formed a metal cap layer (hereinafter referred to as a Co metal cap layer) mainly composed of cobalt (Co) as first barrier layer 24p.

Furthermore, second insulating layer 20 is formed on first barrier layer 24p and first insulating layer 10. Second wiring 22 is formed in second insulating layer 20. Second wiring 22 is a CuAl wiring formed of a CuAl alloy as in the case of first wiring 12. Second wiring 22 is electrically connected to first wiring 12 at its via-plug portion 22v with the plurality of barrier layers 24, namely, the metal cap layer (first barrier layer 24p) and other barrier layers (TaN barrier layer 24t and Ta barrier layer 24s) interposed therebetween. Furthermore, in order to ensure electrical connection between first wiring 12 and second wiring 22, the plurality of barrier layers 24 are formed of a conductive material such as a metal.

As the plurality of barrier layers 24, the Co metal cap layer (first barrier layer 24p), TaN barrier layer 24t, and Ta barrier layer 24s are formed in this order when seen from first wiring 12 between first wiring 12 and second wiring 22, and TaN barrier layer 24t and Ta barrier layer 24s are formed in this order when seen from second insulating layer 20 between second insulating layer 20 and second wiring 22. Here, each of first barrier layer 24p (Co metal cap layer) identified as a CuAl-contact barrier layer which is in contact with first wiring 12 identified as a CuAl wiring, and second barrier layer 24q (Ta barrier layer 24s) identified as a CuAl-contact barrier layer which is in contact with second wiring 22 identified as a CuAl wiring, has a small nitrogen atom content of less than 1 atomic %. Therefore, a high-resistance substance such as AlN is prevented from being formed between first wiring 12 and first barrier layer 24p, and between second wiring 22 and second barrier layer 24q, so that variations in via resistance become small.

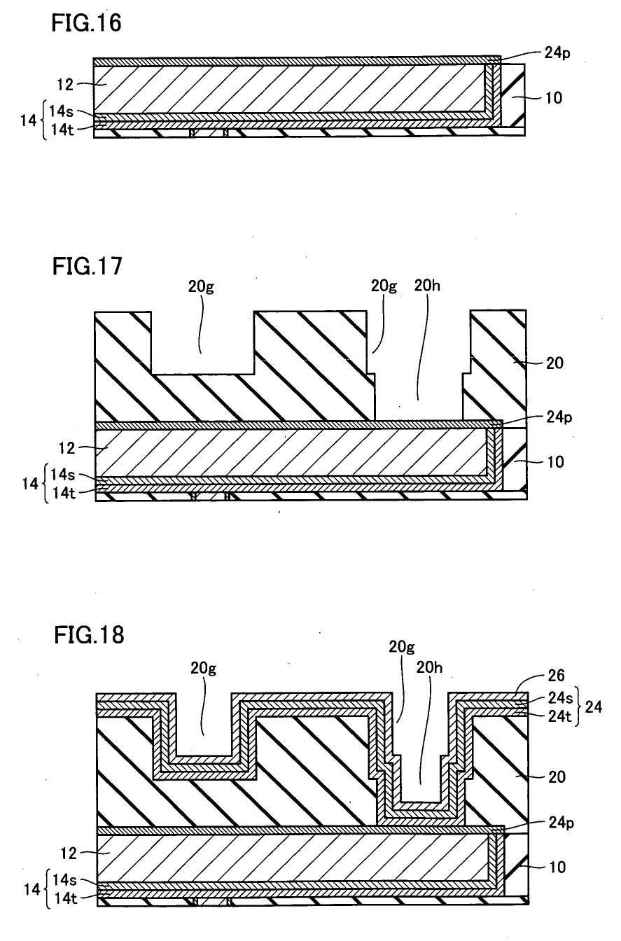

With reference to FIGS. 14-20, a method of manufacturing the semiconductor device according to the present embodiment will hereinafter be described specifically. Note that a portion of base 100 lower than a two-dot chain line L in FIG. 15 is eliminated for simplicity in FIGS. 16-20.

Initially, with reference to FIG. 15, there is prepared first wiring 12 formed in first insulating layer 10 formed on base 100 including semiconductor element 110 (a step of preparing the first wiring). Here, first wiring 12 is a CuAl wiring, and the plurality of barrier layers 14 are TaN barrier layer 14t and Ta barrier layer 14s arranged in this order when seen from first insulating layer 10.

Next, with reference to FIG. 16, on first wiring 12 in the wafer prepared in the above-described step of preparing the first wiring, a metal cap layer mainly composed of Co is selectively formed by an electroless plating method as first barrier layer 24p (a step of selectively forming the metal cap layer (the first barrier layer)).

Next, with reference to FIG. 17, on the Co metal cap layer (first barrier layer 24p) and first insulating layer 10, there is formed an SiO₂ layer as second insulating layer 20 by a CVD method. In second insulating layer 20, trench 20g for wiring and via-hole 20h which reaches first barrier layer 24p are formed by dry etching (a step of forming the trench for wiring and the via-hole).

Next, with reference to FIG. 18, on second insulating layer 20 in which trench 20g for wiring and via-hole 20h are formed and on the Co metal cap layer (first barrier layer 24p), TaN barrier layer 24t and Ta barrier layer 24s are formed in this order as the plurality of barrier layers 24 by a PVD method, and seed layer 26 is formed of a CuAl alloy (a step of forming the barrier layers).

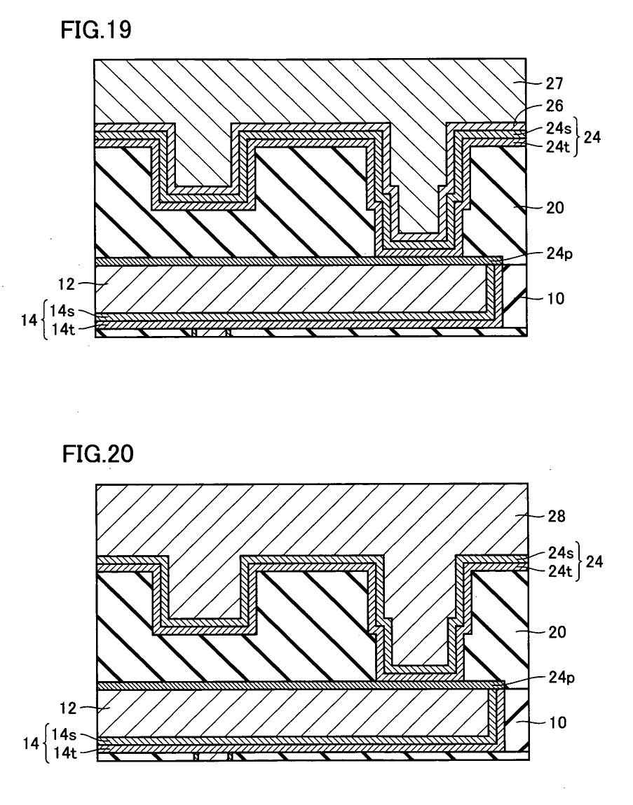

Next, with reference to FIG. 19, Cu layer 27 is formed by a plating method such that Cu layer 27 is embedded in trench 20g for wiring and via-hole 20h in second insulating layer 20 (a step of embedding a wiring material).

Next, with reference to FIG. 20, Al atoms in seed layer 26 formed of a CuAl alloy are diffused into Cu layer 27 by heat treatment to form CuAl layer 28 (a step of processing the wiring material).

Next, with reference to FIG. 14, portions of barrier layers 24 and CuAl layer 28 on the surface of second insulating layer 20 are removed by a CNT method to form second wiring 22 in trench 20g for wiring and via-hole 20h (a step of forming the second wiring).

In the semiconductor device manufactured as such, both of first barrier layer 24p (the Co metal cap layer) and second barrier layer 24q (Ta barrier layer 24s) which are in contact with first wiring 12 and second wiring 22 identified as CuAl wirings, respectively, have a small nitrogen atom content of less than 1 atomic %, so that a high-resistance substance such as AlN is prevented from being formed between the wiring and the barrier layer, and hence variations in via resistance become small.

Furthermore, in the semiconductor device according to the present embodiment, the Co metal cap layer (first barrier layer 24p) which has a nitrogen atom content of less than 1 atomic % is only required to be formed directly on first wiring 12, and hence a structure of barrier layers can be simplified. Furthermore, the present embodiment requires no liner layer provided in the first and second embodiments, and hence a layer structure can be simplified.

Furthermore, in the semiconductor device according to the present embodiment, first barrier layer 24p is a metal cap layer which entirely covers first wiring 12 directly thereon, and hence produces a great effect of preventing diffusion of metal atoms through an upper surface of the wiring serving as a path. Accordingly, reliability of the semiconductor device is further improved.

In the present embodiment, selective forming of the metal cap layer (first barrier layer 24p) directly on first wiring 12 is performed by selectively forming a metal layer mainly composed of Co (e.g. a CoW layer, a CoWP layer, a CoWB layer, and a CoWPB layer) by an electroless plating method. However, selective forming is not particularly limited thereto as long as a barrier layer having a small nitrogen atom content of less than 10 atomic % is selectively formed. Selective forming may be performed by selectively forming a W layer by a selective CVD method.

In the present embodiment, three barrier layers are used at the electrically-connected portion of the wiring, and two barrier layers are used at a portion other than the electrically-connected portion. However, the number of barrier layers 24 is not limited thereto as long as the metal cap layer (first barrier layer 24p) and second barrier layer 24q which are in contact with first wiring 12 and second wiring 22 identified as CuAl wirings, respectively, are barrier layers each having a small nitrogen atom content of less than 10 atomic %. Furthermore, as in the first embodiment, at least one of the plurality of barrier layers preferably has a nitrogen atom content of at least 10 atomic % in the present embodiment.

The present embodiment has been described taking as an example the case where both of the first wiring and the second wiring are CuAl wirings. However, the present embodiment can also be applied to the case where one of the second wiring and the first wiring is a Cu wiring, as long as at least one of the first wiring and the second wiring is a CuAl wiring. If one of the second wiring and the first wiring is a Cu wiring, a barrier layer which is in contact with the Cu wiring may contain nitrogen atoms. Furthermore, if Cu is formed in the insulating layer, the step of processing the wiring material is unnecessary in the manufacturing steps described above.

In the present embodiment, a Ta layer, a Ta alloy layer, and a Ta compound layer are used as the barrier layers. However, the barrier layers are not particularly limited thereto as long as they have barrier properties against Cu atoms. It is possible to use a Ti layer, a Ti alloy layer, and a Ti compound layer, a W layer, a W alloy layer, and a W compound layer, an Ru layer, an Ru alloy layer, and an Ru compound layer, Furthermore, although the present embodiment has been described taking a dual damascene structure as an example, the present embodiment can also be applied to a single damascene structure.

### Fourth Embodiment

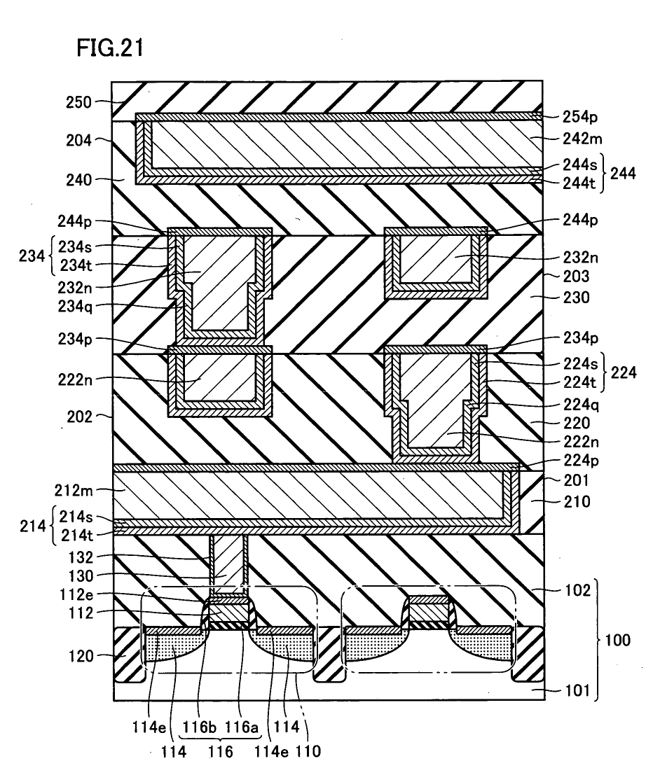

With reference to FIG. 21, a further embodiment of the semiconductor device according to the present invention has a multilayer wiring structure in which at least three layers of wirings are stacked. Here, the multilayer wiring structure includes the first wiring and the second wiring in the first to third embodiments. The multilayer wiring structure may include both of a CuAl wiring and a Cu wiring. In other words, a CuAl wiring is preferably used for a layer where only a small wiring width is allowed and it is difficult to ensure reliability, while a Cu wiring, which has resistance lower than that of the CuAl wiring, is preferably used for a layer where a large wiring width is allowed and reliability can sufficiently be ensured without using the CuAl alloy wiring.

For example, the semiconductor device according to the present embodiment has a four-layer wiring structure. The four-layer wiring structure has an insulating layer 210 and a Cu wiring 212m in a first layer 201, an insulating layer 220 and a CuAl wiring 222n in a second layer 202, an insulating layer 230 and a CuAl wiring 232n in a third layer 203, and an insulating layer 240 and a Cu wiring 242m in a fourth layer 204.

Here, each pair of the wiring in first layer 201 and the wiring in second layer 202, the wiring in second layer 202 and the wiring in third layer 203, and the wiring in third layer 203 and the wiring in fourth layer 204 have the relationship between first wiring 12 and second wiring 22 in any of the first to third embodiments. In other words, Cu wiring 212m (the first wiring) in the first layer and CuAl wiring 222n (the second wiring) in the second layer are electrically connected with a Co metal cap layer (a first barrier layer 224p), a TaN barrier layer 224t, and a Ta barrier layer 224s (a second barrier layer 224q) interposed therebetween. CuAl wiring 222n (the first wiring) in the second layer and CuAl wiring 232n (the second wiring) in the third layer are electrically connected with a Co metal cap layer (a first barrier layer 234p), a TaN barrier layer 234t, and a Ta barrier layer 234s (the second barrier layer 234q) interposed therebetween.

In the present embodiment, a Cu wiring is used for the first layer and the fourth layer, and a CuAl wiring is used for the second layer and the third layer. However, each of a CuAl wiring and a Cu wiring may be used for any layer as long as a CuAl wiring is used.

### Fifth Embodiment

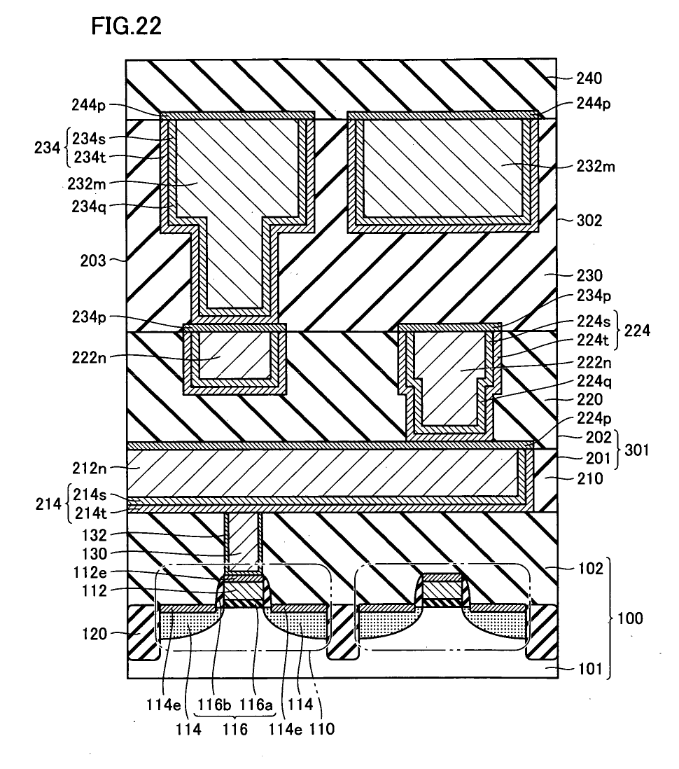

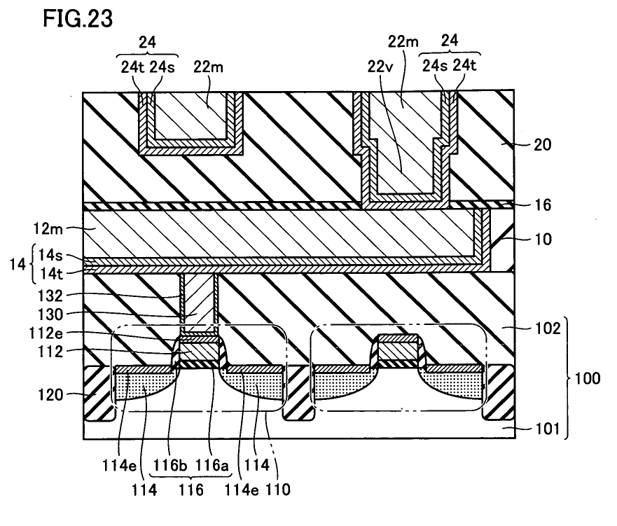

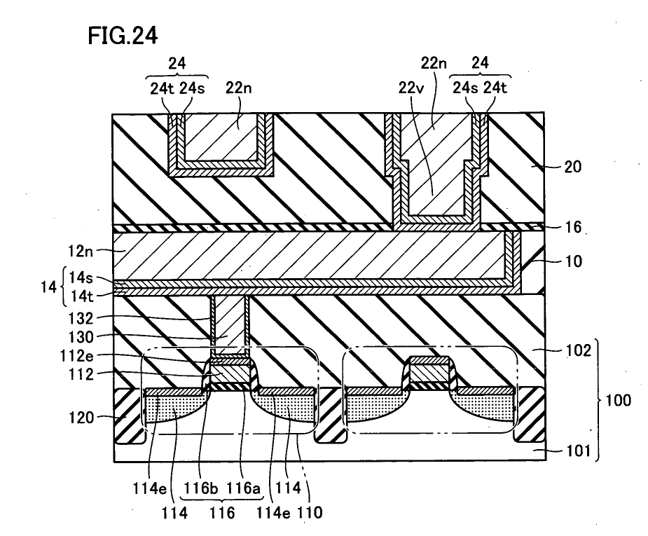

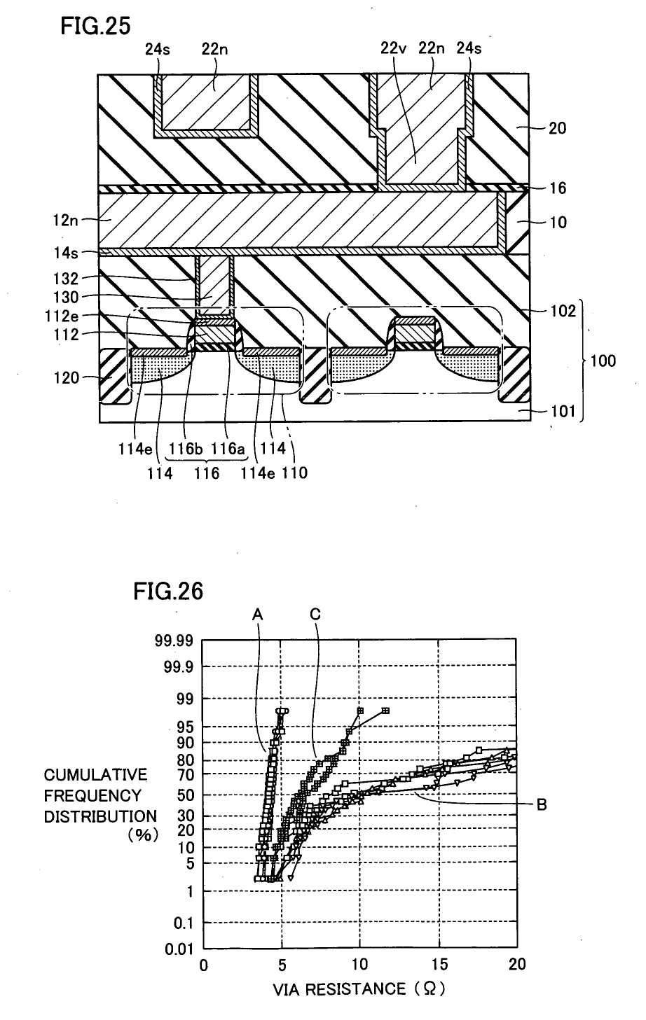

With reference to FIG. 22, a further embodiment of the semiconductor device according to the present invention has a multilayer wiring structure in which at least three layers of wirings are stacked. Here, the multilayer wiring layer includes a lower-layer wiring layer 301 and an upper-layer wiring layer 302. The wiring in lower-layer wiring layer 301 is CuAl wirings 212n, 222n. The wiring in upper-layer wiring layer 302 is a Cu wiring 232m. In the semiconductor device, a CuAl wiring is preferably used for the lower-layer wiring layer because only a small wiring width is allowed and it is difficult to ensure reliability, while a Cu wiring is preferably used for the upper-layer wiring layer so as to reduce resistance.

For example, the semiconductor device according to the present embodiment has a three-layer wiring structure. The three-layer wiring structure has insulating layer 210 and CuAl wiring 212n in first layer 201, insulating layer 220 and CuAl wiring 222n in second layer 202, and insulating layer 230 and Cu wiring 232m in third layer 203.

Here, each pair of the wiring in first layer 201 and the wiring in second layer 202, and the wiring in second layer 202 and the wiring in third layer 203 have the relationship between first wiring 12 and second wiring 22 in any of the first to third embodiments. In other words, CuAl wiring 212n (the first wiring) in the first layer and CuAl wiring 222n (the second wiring) in the second layer are electrically connected with the Co metal cap layer (first barrier layer 224p), TaN barrier layer 224t, and Ta barrier layer 224s (second barrier layer 224q) interposed therebetween. CuAl wiring 222n (the first wiring) in the second layer and Cu wiring 232m (the second wiring) in the third layer are electrically connected with the Co metal cap layer (first barrier layer 234p), TaN barrier layer 234t, and Ta barrier layer 234s (the second barrier layer 234q) interposed therebetween.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device having a first wiring formed in a first insulating layer and a second wiring formed in a second insulating layer formed on said first insulating layer and said first wiring,
at least one of said first wiring and said second wiring being a CuAl wiring,
said second wiring being electrically connected to said first wiring at its via-plug portion, with a plurality of barrier layers interposed between said second wiring and said first wiring, and
in said barrier layers, a CuAl-contact barrier layer which is in contact with said CuAl wiring having a nitrogen atom content of less than 10 atomic %.

2. The semiconductor device according to claim 1, wherein a first barrier layer which is in contact with said first wiring is selectively formed directly below the via-plug portion of said second wiring.

3. The semiconductor device according to claim 1, wherein a first barrier layer which is in contact with said first wiring is selectively formed directly on said first wiring.

4. The semiconductor device according to claim 1, having a multilayer wiring structure in which at least three layers of wirings are stacked, wherein said multilayer wiring structure has said first wiring and said second wiring.

5. The semiconductor device according to claim 4, wherein said multilayer wiring structure includes a lower-layer wiring layer and an upper-layer wiring layer, and a wiring in said lower-layer wiring layer is a CuAl wiring, and a wiring in said upper-layer wiring layer is a Cu wiring.

6. The semiconductor device according to claim 1, wherein at least one of said barrier layers has a nitrogen atom content of at least 10 atomic %.

7. A method of manufacturing a semiconductor device, comprising the steps of:
preparing a first wiring formed in a first insulating layer;
forming a second insulating layer on said first insulating layer and said first wiring;
forming a trench for wiring and a via-hole which reaches said first wiring in said second insulating layer;
forming a plurality of barrier layers in said trench for wiring and said via-hole; and
forming a second wiring on said barrier layers,
at least one of said first wiring and said second wiring being formed of a CuAl alloy, and
in said barrier layers, a CuAl-contact barrier layer which is in contact with a CuAl wiring formed of said CuAl alloy having a nitrogen atom content of less than 10 atomic %.

8. The method of manufacturing the semiconductor device according to claim 7, wherein in the step of forming the plurality of said barrier layers, a first barrier layer which is in contact with said first wiring is selectively formed directly on a bottom surface of said via-hole.

9. A method of manufacturing a semiconductor device, comprising the steps of:
preparing a first wiring formed in a first insulating layer;
selectively forming a first barrier layer directly on said first wiring;
forming a second insulating layer on said first insulating layer and said first barrier layer;
forming a trench for wiring and a via-hole which reaches said first barrier layer in said second insulating layer;
forming at least one additional barrier layer in said trench for wiring and said via-hole; and
forming a second wiring on said additional barrier layer,
at least one of said first wiring and said second wiring being formed of a CuAl alloy, and
a CuAl-contact barrier layer which is in contact with a CuAl wiring formed of said CuAl alloy having a nitrogen atom content of less than 10 atomic %.
